(19) United States
(12) Patent Application Publication
(10) Pub. No.: US 2007/0151517 A1
(43) Pub. Date: Jul. 5, 2007

(54) HEATER FOR DEPOSITING THIN FILM

(75) Inventors: Choon Kum BAIK, Pyungtaek-city (KR); Ki Hoon LEE, Pyungtaek-city (KR); Hyung Sub CHOI, Pyungtaek-city (KR); Kang Jin SEO, Anseong-city (KR)

Correspondence Address: CANTOR COLBURN, LLP, 55 GRIFFIN ROAD SOUTH, BLOOMFIELD, CT, 06002, US

(73) Assignee: IPS LTD., Pyungtaek-city (KR)

(21) Appl. No.: 11/564,554

(22) Filed: Nov. 29, 2006

(30) Foreign Application Priority Data
Dec. 31, 2005 (KR) 10-2005-0136268

(51) Int. Cl. C23C 16/00

(52) U.S. Cl. 118/725

(57) ABSTRACT

A heater for depositing a thin film to deposit a thin film on a seated wafer by heating is provided. The heater for depositing a thin film includes: a wafer supporting plate on which a wafer is seated and a plurality of injection holes are disposed at the edge of the wafer supporting plate and in which a heat generating member is included; a shaft disposed at the lower side of the wafer supporting plate which comprises an inert gas pathway through which inert gas is provided; and a flow channel forming cover bonded to the lower part of the wafer supporting plate, and comprising an inner space formed between the flow channel forming cover and the wafer supporting plate, wherein the injection holes and the inert gas pathway are connected via the inner space.

### CROSS-REFERENCE TO RELATED PATENT APPLICATION

This application claims the benefit of Korean Patent Application No. 10-2005-0136268, filed on Dec. 31, 2005, in the Korean Intellectual Property Office, the disclosure of which is incorporated herein in its entirety by reference.

### BACKGROUND OF THE INVENTION

1. Field of the Invention

The present invention relates to a heater for depositing a thin film on a seated wafer by heating.

2. Description of the Related Art

FIG. 1 is a side cross-sectional view of a conventional heater for depositing a thin film 10. Referring to FIG. 1, the conventional heater for depositing a thin film 10 mainly includes a wafer supporting plate 11 on which a wafer is seated and in which a heat generating member H is included and a shaft 12 which supports the wafer supporting plate 11. A plurality of injection holes 13A are disposed at the edge of the wafer supporting plate 11 and an injection hole flow channel 13B connecting with the injection holes 13A is disposed in a radial and a horizontal direction in the wafer supporting plate 11. An inert gas pathway 13C connecting with the injection hole flow channel 13B is formed in the shaft 12. In addition, a plurality of adsorption holes 14A are formed in the upper surface of the wafer supporting plate 11 to absorb wafer, and a vacuum forming pathway 14B connecting with the adsorption holes 14A is formed in the shaft 12.

In the conventional heater for depositing a thin film 10, a vacuum is formed through the vacuum forming pathway 14B in order to immobilize the wafer which is seated on the heater for depositing a thin film 10 so as to form vacuum pressure in the adsorption holes 14A. In addition, inert gas is provided through the inert gas pathway 13C and then is provided to an inner chamber through the injection holes 13A so as to perform purging or cleaning.

As illustrated in FIG. 1, the injection hole flow channel 13B which is connected with the injection holes 13A is formed in a radial and a horizontal direction in the wafer supporting plate 11. It is very difficult to manufacture such injection hole flow channel 13B.

In addition, if the wafer is slightly warped, a very small space may be formed between the wafer and the wafer supporting plate 11. Due to this small space, adhesion for adhering the wafer to the surface of the wafer supporting plate 11 is decreased, and also, minute vibration may be generated from the wafer. Therefore, uniformity and quality of a thin film formed on the wafer is decreased.

### SUMMARY OF THE INVENTION

The present invention provides a heater for depositing a thin film in which a flow channel is not needed to be formed in a radial and a horizontal direction in a wafer supporting plate so as to manufacture the heater for depositing a thin film easily and a wafer is strongly adhered to the wafer supporting plate, even if the wafer is slightly warped.

According to an aspect of the present invention, there is provided a heater for depositing a thin film including: a wafer supporting plate on which a wafer is seated and a plurality of injection holes are disposed at the edge of the wafer supporting plate and in which a heat generating member is included; a shaft disposed at the lower side of the wafer supporting plate which comprises an inert gas pathway through which inert gas is provided; and a flow channel forming cover bonded to the lower part of the wafer supporting plate, and comprising an inner space formed between the flow channel forming cover and the wafer supporting plate, wherein the injection holes and the inert gas pathway are connected via the inner space.

The wafer supporting plate may include an intermediation flow channel which connects the inert gas pathway with the inner space.

The intermediation flow channel may extend downwards from the upper end of the inert gas pathway to the lower surface of the wafer supporting plate.

The flow channel forming cover may include a penetrating hole through which the shaft penetrates, in the center portion of the flow channel forming cover.

The flow channel forming cover may have a ring shape and include a ring-shaped outer projecting part formed at the outer edge of the flow channel forming cover and a ring-shaped inner projecting part formed at the inner edge of the flow channel forming cover, wherein the outer projecting part and the inner projecting part project upwardly, and wherein the inner space is defined by the lower surface of the wafer supporting plate, the inner circumferential surface of the outer projecting part, the outer circumferential surface of the inner projecting part, and the upper surface of the flow channel forming cover.

The shaft may include a vacuum forming path for forming vacuum pressure, and the wafer supporting plate may include a settling unit on which the wafer is seated, wherein the settling unit includes a plurality of protrusions on which the wafer is placed and an adsorption hole which is connected with the vacuum forming path.

The heater for depositing a thin film may further include a plurality of connecting members which penetrate the flow channel forming cover and are screwed into the wafer supporting plate, the connecting members comprising first supporting pin penetration holes through which supporting pins penetrate, the supporting pins supporting and elevating the wafer when loading and unloading of the wafer, in the center of the connecting members, and the wafer supporting plate comprising second supporting pin penetration holes, which are coaxially disposed with respect to the first supporting pin penetration holes, for the supporting pins to be projected to the upper side of the wafer supporting plate.

### BRIEF DESCRIPTION OF THE DRAWINGS

The above and other features and advantages of the present invention will become more apparent by describing in detail exemplary embodiments thereof with reference to the attached drawings in which:

FIG. 1 is a side cross-sectional view of a conventional heater for depositing a thin film;

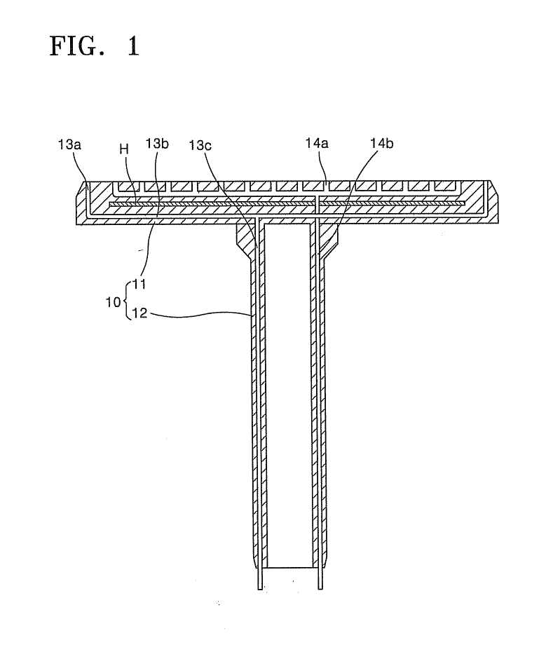

FIG. 2 is an exploded perspective view of a heater for depositing a thin film according to an embodiment of the present invention;

FIG. 3 is a side cross-sectional view of the heater for depositing a thin film of FIG. 2, according to an embodiment of the present invention; and

FIG. 4 is a top view of the heater for depositing a thin film of FIG. 2, according to an embodiment of the present invention.

### DETAILED DESCRIPTION OF THE INVENTION

Hereinafter, the present invention will be described more fully with reference to the accompanying drawings, in which exemplary embodiments of the invention are shown.

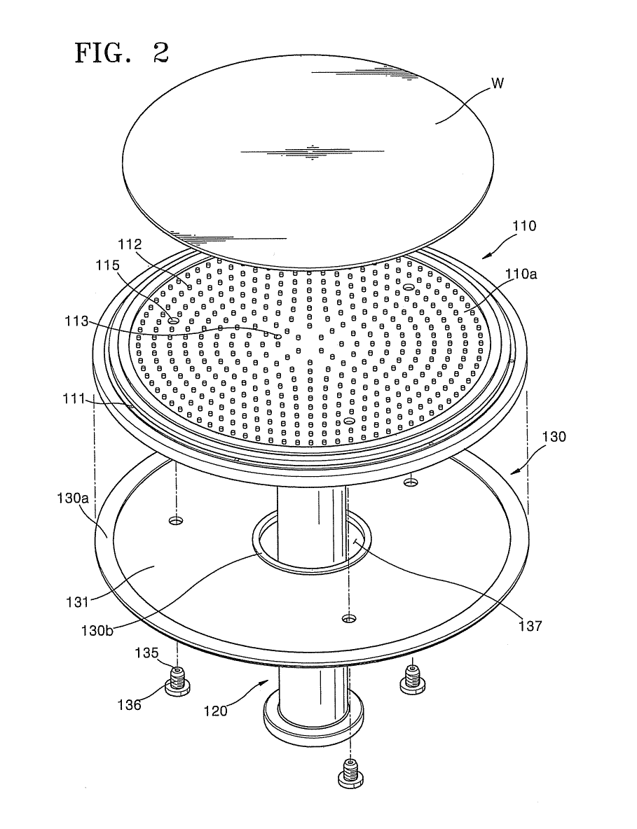

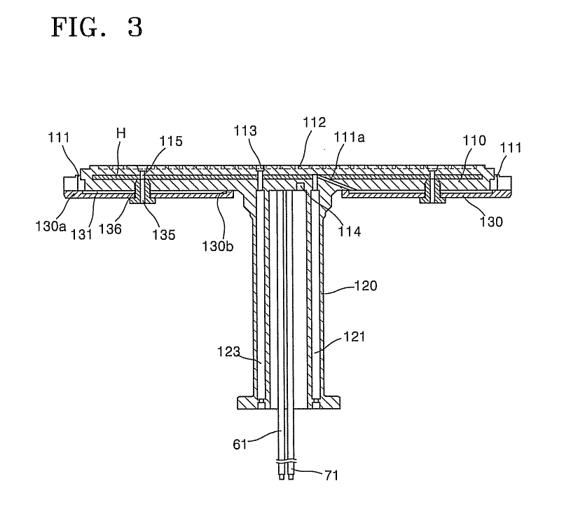

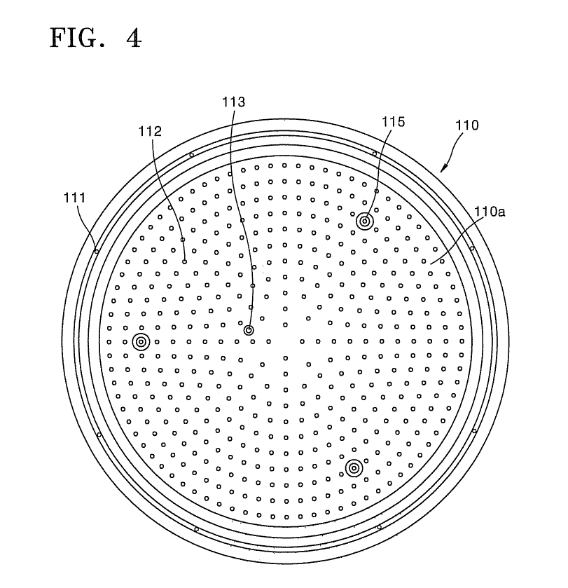

FIG. 2 is an exploded perspective view of a heater for depositing a thin film according to an embodiment of the present invention; FIG. 3 is a side cross-sectional view of the heater for depositing a thin film of FIG. 2; and FIG. 4 is a top view of the heater for depositing a thin film of FIG. 2.

Referring to FIGS. 2 through 4, the heater for depositing a thin film according to an embodiment of the present invention includes a wafer supporting plate 110, a shaft 120, and a flow channel forming cover 130. The wafer supporting plate 110, on which a wafer W is seated, includes a plurality of injection holes 111 at the edge thereof. Inert gas provided to be used in a thin film depositing process is injected to the upper part of the wafer supporting plate 110 through the injection holes 111.

In the wafer supporting plate 110, a heat generating member H and a thermocouple insertion hole 114 for inserting a thermocouple (not illustrated) are formed. The thermocouple installed in the thermocouple insertion hole 114 measures the temperature of the wafer supporting plate 110 and generates corresponding signals, wherein the signals are used to control an operation of the heat generating member H.

A settling unit 110A on which the wafer W is seated is formed on the wafer supporting plate 110. In the settling unit 110A, a plurality of protrusions 112 are disposed on which the wafer W is placed. An adsorption hole 113 which is connected with a vacuum-forming path 123 included in the shaft 120 is formed between the protrusions 112 and will be described later.

The shaft 120 is disposed at the lower side of the wafer supporting plate 110 to support the wafer supporting plate 110. The shaft 120 includes an inert gas pathway 121 through which inert gas is provided and a vacuum-forming path 123 for forming vacuum pressure. In addition, electric wires 61 and 71 are installed in the shaft 120 for providing power to the heat generating member H and a RF electrode included in the wafer supporting plate 110, respectively.

The flow channel forming cover 130 is bonded to the lower part of the wafer supporting plate 110, and an inner space 131 is formed between the flow channel forming cover 130 and the wafer supporting plate 110. The flow channel forming cover 130 has a ring shape and includes a penetrating hole 137 through which the shaft 120 penetrates, in the center portion of the he flow channel forming cover 130. A ring-shaped outer projecting part 130A is formed at the outer edge of the flow channel forming cover 130, wherein the outer projecting part 130A projects upwards. In addition, a ring-shaped inner projecting part 130B is formed at the inner edge of the flow channel forming cover 130, whereby the inner projecting part 130B projects upwards. Since the outer projecting part 130A and the inner projecting part 130B project upwards, the inner space 131 is naturally formed between the outer projecting part 130A and the inner projecting part 130B. In other words, the inner space 131 is defined by the lower surface of the wafer supporting plate 110, the inner circumferential surface of the outer projecting part 130A, the outer circumferential surface of the inner projecting part 130B, and the upper surface of the flow channel forming cover 130. While the outer projecting part 130A and the inner projecting part 130B are adhered to the lower surface of the wafer supporting plate 110, the flow channel forming cover 130 is screwed onto the wafer supporting plate 110 using a plurality of connecting members 136.

On the other hand, an intermediation flow channel 111A which connects the inert gas pathway 121 of the shaft 120 with the inner space 131 of the flow channel forming cover 130 is formed in the wafer supporting plate 110. The intermediation flow channel 111A extends downwards from the upper end of the inert gas pathway 121 to the lower surface of the wafer supporting plate 110. Therefore, inert gas provided through the inert gas pathway 121 passes through the intermediation flow channel 111A, the inner space 131, and the injection hole 111 to be injected to the upper part of the wafer supporting plate 110.

A plurality of the connecting members 136 penetrate the flow channel forming cover 130 and are screwed into the wafer supporting plate 110. A plurality of first supporting pin penetration hole 135 through which supporting pins (not illustrated) penetrate, the supporting pins supporting and elevating the wafer when loading and unloading the wafer, are formed in the center of the connecting members 136.

On the other hand, a plurality of second supporting pin penetration holes 115 which are coaxially disposed with respect to the first supporting pin penetration holes 135, are formed on the wafer supporting plate 110.

The first supporting pin penetration holes 135 and the second supporting pin penetration holes 115 have the same diameter and are connected to each other. Thus, the supporting pins penetrate the first and second supporting pin penetration holes 135 and 115 from the lower side of the flow channel forming cover 130 and are projected to the upper side of the wafer supporting plate 110. In the present embodiment, 3 first supporting pin penetration holes 135 and second supporting pin penetration holes 115 are used.

As described above, the heater for depositing a thin film according to the present invention includes a wafer supporting plate and a flow channel forming cover which is bonded to the lower part of the wafer supporting plate. Therefore, the flow channel does not need to be formed in a radial and a horizontal direction and thus manufacturing of the heater for depositing a thin film is easy.

In addition, since a number of protrusions are employed and adsorption holes are interposed between the protrusions, strong adsorption of the wafer is possible, even the wafer is slightly warped, and the wafer is prevented from vibrating. Subsequently, uniformity and quality of a thin film formed on the wafer is increased.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A heater for depositing a thin film comprising: a wafer supporting plate on which a wafer is seated and a plurality of injection holes are disposed at the edge of the wafer supporting plate and in which a heat generating member is included;
a shaft disposed at the lower side of the wafer supporting plate which comprises an inert gas pathway through which inert gas is provided; and
a flow channel forming cover bonded to the lower part of the wafer supporting plate, and comprising an inner space formed between the flow channel forming cover and the wafer supporting plate, wherein the injection holes and the inert gas pathway are connected via the inner space.

2. The heater for depositing a thin film of claim 1, wherein the wafer supporting plate comprises an intermediation flow channel which connects the inert gas pathway with the inner space.

3. The heater for depositing a thin film of claim 2, wherein the intermediation flow channel extends downwards from the upper end of the inert gas pathway to the lower surface of the wafer supporting plate.

4. The heater for depositing a thin film of claim 1, wherein the flow channel forming cover comprises a penetrating hole through which the shaft penetrates, in the center portion of the flow channel forming cover.

5. The heater for depositing a thin film of claim 4, wherein the flow channel forming cover has a ring shape and comprises a ring-shaped outer projecting part formed at the outer edge of the flow channel forming cover and a ring-shaped inner projecting part formed at the inner edge of the flow channel forming cover, wherein the outer projecting part and the inner projecting part project upwardly, and wherein the inner space is defined by the lower surface of the wafer supporting plate, the inner circumferential surface of the outer projecting part, the outer circumferential surface of the inner projecting part, and the upper surface of the flow channel forming cover.

6. The heater for depositing a thin film of claim 1, wherein the shaft comprises a vacuum forming path for forming vacuum pressure, and the wafer supporting plate comprises a settling unit on which the wafer is seated, wherein the settling unit comprises a plurality of protrusions on which the wafer is placed and an adsorption hole which is connected with the vacuum forming path.

7. The heater for depositing a thin film of claim 1, further comprising a plurality of connecting members which penetrate the flow channel forming cover and are screwed into the wafer supporting plate, the connecting members comprising first supporting pin penetration holes through which supporting pins penetrate, the supporting pins supporting and elevating the wafer when loading and unloading of the wafer, in the center of the connecting members, and the wafer supporting plate comprising second supporting pin penetration holes, which are coaxially disposed with respect to the first supporting pin penetration holes, for the supporting pins to be projected to the upper side of the wafer supporting plate.
